(19) United States
(12) Patent Application Publication
(10) Pub. No.: US 2026/0339303 A1
(43) Pub. Date: Oct. 29, 2026

(54) SEMICONDUCTOR DEVICE MANUFACTURING SYSTEM, SERVER, AND SEMICONDUCTOR DEVICE MANUFACTURING METHOD

(71) Applicant: HITACHI HIGH-TECH CORPORATION, Minato-ku, Tokyo (JP)

(72) Inventors: Yusuke NAGAMITSU, Tokyo (JP); Go SAITO, Tokyo (JP); Toru ARAMAKI, Tokyo (JP)

(21) Appl. No.: 19/099,160

(22) PCT Filed: Nov. 2, 2023
(86) PCT No.: PCT/JP2023/039605

§ 371 Date: Jan. 28, 2025

(51) Int. Cl. G05B 19/418

(52) U.S. Cl. CPC G05B 19/41865; G05B 2219/45031

(57) ABSTRACT

Provided is a semiconductor device manufacturing system capable of creating a recipe that can be processed by a semiconductor manufacturing device in another base even when a device specification is different. The semiconductor device manufacturing system transfers a manufacturing condition of a first semiconductor manufacturing device (101) in a first base (A) to a second semiconductor manufacturing device (111) in a second base (B) to process a sample by the second semiconductor manufacturing device (111). When a specification of the first semiconductor manufacturing device (101) and a specification of the second semiconductor manufacturing device (111) are different from each other and the manufacturing condition of the first semiconductor manufacturing device (101) is transferred to the second semiconductor manufacturing device (111), a manufacturing condition generated by adapting a parameter item in the manufacturing condition of the first semiconductor manufacturing device (101) to a parameter item in a manufacturing condition of the second semiconductor manufacturing device (111) is transferred to the second semiconductor manufacturing device (111).

### TECHNICAL FIELD

The present invention relates to a semiconductor device manufacturing system, a server, and a semiconductor device manufacturing method.

### BACKGROUND ART

A semiconductor manufacturing device differs in a recipe for each device specification. Therefore, in the case of preparing a recipe of a semiconductor manufacturing device, it is basically necessary to deliver a material describing the recipe, and exchange an evaluation result and information about the recipe over telephone or in a meeting. The recipe includes a plurality of steps, and parameter conversion is necessary depending on a device specification. In the related art, a person checks a specification to confirm a device specification difference and creates a recipe that can be processed by rewriting a parameter that needs to be converted based on the specification difference.

On the other hand, PTL 1 discloses a technique for automatically converting a recipe (parameter file) for another exposure device into a recipe adapted for an own device (exposure device). Specifically, a recipe is changed to a parameter configuration adapted for a transfer destination device, a parameter and a value thereof are acquired from a configuration file, and a value of each parameter of the converted recipe is changed based on the parameter and is stored in a memory.

### CITATION LIST

### Patent Literature

PTL 1: JP2003-37051A

### SUMMARY OF INVENTION

### Technical Problem

As described above, when preparing a recipe in the related art, it is basic to deliver a material describing the recipe, and exchange an evaluation result and information on the recipe over telephone or in a meeting. Therefore, a time lag occurs before evaluation is started after an evaluation request is received over telephone or in a meeting, and it takes time to prepare the recipe.

When there is a device specification difference between devices, a recipe parameter conversion is required. Since the parameter conversion is performed manually, a conversion error may cause a device trouble or failure. In recipe confirmation, it is necessary to confirm a parameter conversion item due to a device specification difference in all steps, which takes a huge amount of time.

On the other hand, PTL 1 discloses a system for converting a recipe of another exposure device into an equivalent result when the recipe is transferred to another exposure device. Therefore, when a device specification configuration is different, there is a problem that conversion is not possible.

The invention has been made in view of the above problems, and an object of the invention is to provide a semiconductor device manufacturing system, a server, and a semiconductor device manufacturing method capable of creating a recipe that can be processed by a semiconductor manufacturing device in another base even when a device specification is different.

### Solution to Problem

In order to achieve the above object, a representative semiconductor device manufacturing system according to the invention transfers a manufacturing condition of a first semiconductor manufacturing device in a first base to a second semiconductor manufacturing device in a second base to process a sample by the second semiconductor manufacturing device. When a specification of the first semiconductor manufacturing device and a specification of the second semiconductor manufacturing device are different from each other and the manufacturing condition of the first semiconductor manufacturing device is transferred to the second semiconductor manufacturing device, a manufacturing condition generated by adapting a parameter item in the manufacturing condition of the first semiconductor manufacturing device to a parameter item in a manufacturing condition of the second semiconductor manufacturing device is transferred to the second semiconductor manufacturing device.

Further, a semiconductor device manufacturing method according to the invention is a semiconductor device manufacturing method for transferring a manufacturing condition of a first semiconductor manufacturing device in a first base to a second semiconductor manufacturing device in a second base to process a sample by the second semiconductor manufacturing device. When a specification of the first semiconductor manufacturing device and a specification of the second semiconductor manufacturing device are different from each other and the manufacturing condition of the first semiconductor manufacturing device is transferred to the second semiconductor manufacturing device, a manufacturing condition generated by adapting a parameter item in the manufacturing condition of the first semiconductor manufacturing device to a parameter item in a manufacturing condition of the second semiconductor manufacturing device is transferred to the second semiconductor manufacturing device.

### Advantageous Effects of Invention

According to the invention, it is possible to create a recipe that can be processed by a semiconductor manufacturing device in another base even when a device specification is different.

Problems, configurations, and effects other than those described above will be clarified by the following embodiments.

### BRIEF DESCRIPTION OF DRAWINGS

FIG. 1 is a block diagram showing a computer system for implementing an aspect of an embodiment according to the present disclosure.

FIG. 2 is a system configuration diagram showing an embodiment of a semiconductor device manufacturing system according to the invention.

FIG. 3 is a diagram showing an example of a processing flow from selecting a recipe to be evaluated to transferring an evaluation result according to the invention.

FIG. 4 is a diagram showing an example of a processing flow of creating a recipe according to the invention.

### DESCRIPTION OF EMBODIMENTS

Embodiments of the invention will be described.

### <Computer System for Implementing Aspect of Embodiment>

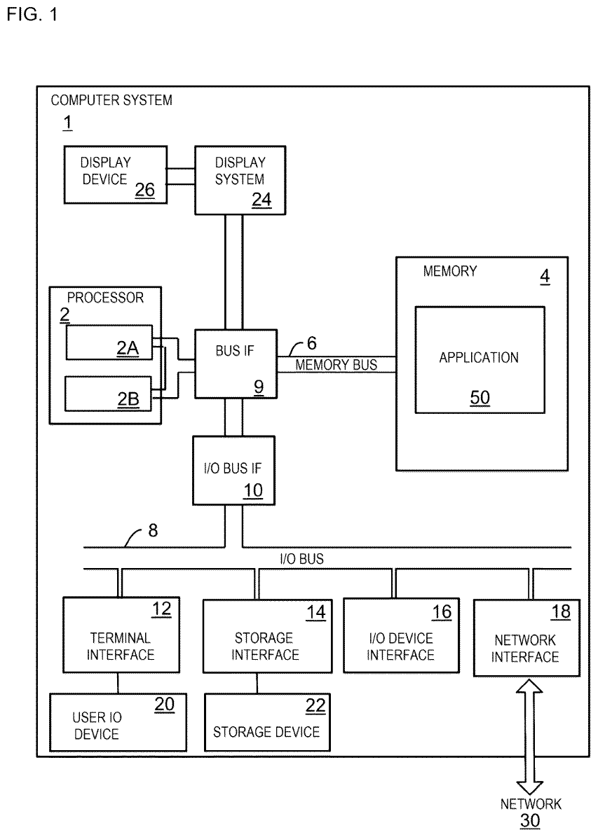

FIG. 1 is a block diagram showing a computer system 1 for implementing an aspect of an embodiment according to the present disclosure. Mechanisms and devices of various embodiments disclosed in the specification may be applied to any appropriate computing system. Main components of the computer system 1 include one or more processors 2, a memory 4, a terminal interface 12, a storage interface 14, an input and output (I/O) device interface 16, and a network interface 18. These components may be mutually connected via a memory bus 6, an I/O bus 8, a bus interface unit 9, and an I/O bus interface unit 10.

The computer system 1 may include one or more processing devices 2A and 2B which are generically referred to as the processor 2. Each processor 2 may execute a command stored in the memory 4 and include an on-board cache. In one embodiment, the computer system 1 may include a plurality of processors, and in another embodiment, the computer system 1 may be a system implemented by a single processing device. The processing device may be a central processing unit (CPU), a field-programmable gate array (FPGA), a graphics processing unit (GPU), a digital signal processor (DSP), or the like.

In one embodiment, the memory 4 may include a random access semiconductor memory, a storage device, or a storage medium (either volatile or nonvolatile) for storing data and programs. In one embodiment, the memory 4 represents all virtual memories of the computer system 1, and may include a virtual memory of another computer system connected to the computer system 1 via a network. The memory 4 may be conceptually regarded as a single memory, but in another embodiment, the memory 4 may have a more complicated configuration such as a hierarchy of caches and other memory devices. For example, the memory may be caches of a plurality of levels, and the caches may be divided for each function. As a result, one cache may store a command and the other caches may store non-command data used by a processor. The memory may be distributed as in a so-called non-uniform memory access (NUMA) computer architecture, and may be associated with various different processing devices.

The memory 4 may store all or a part of a program, a module, and a data structure for implementing functions described in the present specification. For example, the memory 4 may store a latent factor specifying application 50. In one embodiment, the latent factor specifying application 50 may include a command or a description to be performed on the processor 2 by a function to be described later, or may include a command or a description interpreted according to another command or description. In one embodiment, the latent factor specifying application 50 may be implemented by hardware via a semiconductor device, a chip, a logic gate, a circuit, a circuit card, and/or another physical hardware device, instead of a processor-based system or in addition to a processor-based system. In one embodiment, the latent factor specifying application 50 may include data other than a command or a description. In one embodiment, a camera, a sensor, or other data input devices (not shown) may be provided to directly communicate with the bus interface unit 9, the processor 2, or another hardware of the computer system 1. Such a configuration may reduce the necessity of the processor 2 accessing the memory 4 and the latent factor identification application.

The computer system 1 may include the bus interface unit 9 that performs communication among the processor 2, the memory 4, a display system 24, and the I/O bus interface unit 10. The I/O bus interface unit 10 may be connected to the I/O bus 8 for transferring data to and from various I/O units. The I/O bus interface unit 10 may communicate with a plurality of I/O interface units 12, 14, 16, and 18 which are known as an I/O processor (IOP) or an I/O adapter (IOA) via the I/O bus 8. The display system 24 may include a display controller, a display memory, or may include both a display controller and a display memory. The display controller can provide video, audio, or both video and audio to a display device 26. The computer system 1 may include one or a plurality of devices such as sensors configured to collect data and provide the data to the processor 2. The display memory may be a dedicated memory for buffering video data. The display system 24 may be connected to the display device 26 such as a stand-alone display screen, a television, a tablet, or a portable device. In one embodiment, the display device 26 may include a speaker for rendering audio. Alternatively, a speaker for rendering audio may be connected to an I/O interface unit. In another embodiment, a function provided by the display system 24 may be implemented by an integrated circuit including the processor 2. Similarly, a function provided by the bus interface unit 9 may be implemented by an integrated circuit including the processor 2.

The I/O interface unit has a function of communicating with various storages or I/O devices. For example, a user I/O device 20, for example, a user output device such as a video display device and a speaker television, or a user input device such as a keyboard, a mouse, a keypad, a touch pad, a track ball, a button, a light pen, or another pointing device, can be attached to the terminal interface unit 12. A user may input input data or an instruction to the user I/O device 20 and the computer system 1 and receive output data from the computer system 1 by operating a user input device using a user interface. The user interface may be, for example, displayed on a display device via the user I/O device 20, replayed by a speaker, or printed via a printer.

One or more disk drives or direct access storage devices 22 (usually magnetic disk drive storage devices, and may be an array of disk drives implemented to be regarded as a single disk drive or another storage device) can be attached to the storage interface 14. In one embodiment, the storage device 22 may be configured as any secondary storage device. Contents of the memory 4 are stored in the storage device 22, and may be read from the storage device 22 as necessary. The network interface 18 may provide a communication route so that the computer system 1 and other devices can communicate with each other. The communication route may be, for example, a network 30.

Although the computer system 1 shown in FIG. 1 has a bus structure that provides a direct communication route among the processor 2, the memory 4, the bus interface 9, the display system 24, and the I/O bus interface unit 10, in another embodiment, the computer system 1 may include point-to-point links, multiple hierarchical buses, parallel or redundant communication routes in a hierarchical, star or web configuration. Further, although the I/O bus interface unit 10 and the I/O bus 8 are shown as a single unit, in practice, the computer system 1 may include a plurality of the I/O bus interface units 10 or a plurality of the I/O buses 8. Further, although a plurality of I/O interface units for separating the I/O bus 8 from various communication routes connected to various I/O devices are shown, in another embodiment, some or all of the I/O devices may be directly connected to a single system I/O bus.

In one embodiment, the computer system 1 may be a device that receives a request from another computer system (client) without a direct user interface, such as a multi-user mainframe computer system, a single user system, and a server computer. In another embodiment, the computer system 1 may be a desktop computer, a portable computer, a notebook computer, a tablet computer, a pocket computer, a telephone, a smartphone, or any other appropriate electronic devices.

### <System Configuration Diagram>

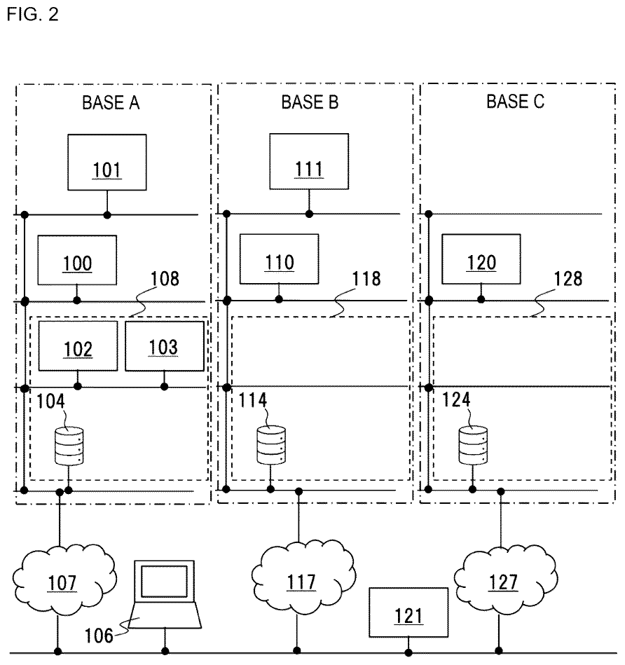

FIG. 2 is a system configuration diagram showing an embodiment of a semiconductor device manufacturing system according to the invention.

FIG. 2 shows a case where there are three bases of a base A, a base B, and a base C. Here, the base is a location where a predetermined activity is performed, and in the base, information can be exchanged through an independent network within the base. A specific example of the base includes a business office, a research facility, a production factory, and the like of a company. For example, in the case of a “production base”, there is equipment such as a production device, and the production base refers to a location where production and activities related to production can be performed.

In the base A, a semiconductor manufacturing line PC group 101, an in-base PC 100, a gateway PC 102, a data route setting PC 103, and a server 104 are provided. The gateway PC 102, the data route setting PC 103, and the server 104 are provided in an integrated platform 108 provided in the base A. The base A is configured such that information can be exchanged with another base, an external PC 121 used by a home worker or the like, and a remote monitor 106 via an Internet 107.

In the base B, a semiconductor manufacturing line PC group 111, an in-base PC 110, and a server 114 are provided. The server 114 is provided in an integrated platform 118 provided in the base B. The base B is configured such that information can be exchanged with another base, the external PC 121, and the remote monitor 106 via an Internet 117.

In the base C, an in-base PC 120 and a server 124 are provided. The server 124 is provided in an integrated platform 128 provided in the base C. The base C is configured such that information can be exchanged with another base, the external PC 121, and the remote monitor 106 via and an Internet 127.

In the base A and the base B, a semiconductor manufacturing device is provided, and processing of a sample or the like can be performed. Further, in the base A and the base B, an evaluation device such as a semiconductor inspection device, a semiconductor analysis device, and a semiconductor analyzer are provided. In addition to an etching device, the semiconductor manufacturing device may include a plasma CVD device, an assembly device, a surface modification device, and the like. The bases A and B can be assumed to be a semiconductor manufacturing factory, but the invention is not limited thereto. For example, each of the base A and the base B may be a line for development or a line for trial production. The semiconductor inspection device, the semiconductor analysis device, and the semiconductor analyzer inspect, analyze, and evaluate an evaluation target processed by the semiconductor manufacturing device. At least one of the semiconductor inspection device, the semiconductor analysis device, and the semiconductor analyzer may be provided. On the other hand, the base C is an example in which no semiconductor manufacturing device is provided.

The integrated platforms 108, 118, and 128 can be applied as a common platform in which a gateway PC, a data route setting PC, and a server can be provided. However, the base B and the base C are an example in which no gateway PC and no data route setting PC is provided.

The semiconductor manufacturing line PC group 101 controls the semiconductor manufacturing device and the like constituting a manufacturing line in the base A. The semiconductor manufacturing line PC group 101 controls the semiconductor manufacturing device in the base A based on a processing recipe related to a process sequence or a control parameter, and acquires data indicating a result of processing performed by the semiconductor manufacturing device. The acquired data is sent to the server 104 via the gateway PC 102. The semiconductor manufacturing line PC group 101 includes a plurality of computers. The semiconductor manufacturing line PC group 101 may be implemented by one computer. Similarly, the semiconductor manufacturing line PC group 101 can control a semiconductor inspection device, a semiconductor analysis device, and a semiconductor analyzer in the base A.

The semiconductor manufacturing line PC group 111 controls the semiconductor manufacturing device and the like constituting a manufacturing line in the base B. The semiconductor manufacturing line PC group 111 controls the semiconductor manufacturing device in the base B based on a processing recipe related to a process sequence and a control parameter, and acquires data indicating a result of processing performed by the semiconductor manufacturing device. The acquired data is sent to the server 114. The semiconductor manufacturing line PC group 111 includes a plurality of computers. The semiconductor manufacturing line PC group 111 may be implemented by one computer. Similarly, the semiconductor manufacturing line PC group 111 can control a semiconductor inspection device, a semiconductor analysis device, and a semiconductor analyzer in the base B.

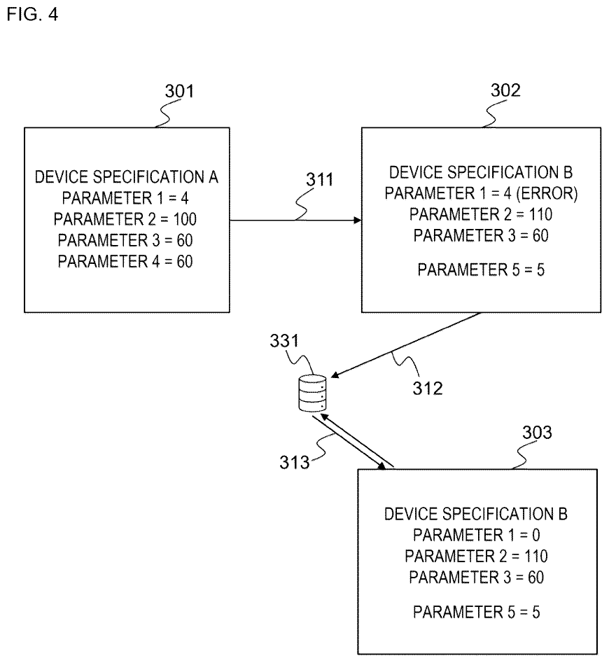

Each of the servers 104 and 114 records a device specification of the semiconductor manufacturing device belonging to an own base. Each of the server 104, 114, and 124 can store a device specification of a semiconductor manufacturing device of another base. Further, a device specification of a semiconductor manufacturing device may be acquired from another base. Each of the servers 104, 114, and 124 records a recipe and a device specification of a semiconductor manufacturing device belonging to an own base or another base, which are evaluated in the past. The recipe is a condition for processing (for example, machining) an evaluation target by a semiconductor manufacturing device. For example, an etching device which is a semiconductor manufacturing device includes a condition for performing etching processing. Further, the recipe may include a recipe for inspection and analysis processing in a semiconductor inspection device, a semiconductor analysis device, and a semiconductor analyzer. The device specification is a specification for operating a corresponding semiconductor manufacturing device or the like, and includes parameter items as described later with reference to FIG. 4. A range of each parameter is determined by a device specification, and the recipe is in a state in which the parameter is defined.

The in-base PC 100 in the A base can access the semiconductor manufacturing line PC group 101, the integrated platform 108, and the server 104. The in-base PC 110 in the base B can access the semiconductor manufacturing line PC group 111, the integrated platform 118, and the server 114. The in-base PC 120 in the base C can access the integrated platform 128 and the server 124. Further, the in-base PCs 100, 110, and 120 can access an integrated platform or a server in another base through authentication to be described later. Further, the external PC 121 and the remote monitor 106 can access an integrated platform or a server in each base through authentication to be described later.

In the base A, for example, a processing recipe for performing etching processing in a semiconductor manufacturing device is input to the semiconductor manufacturing line PC group 101 and performed. After the processing recipe is performed, the etching device transmits an instruction value corresponding to contents of the recipe to each device in the etching device to perform etching processing. The processed recipe is stored in the semiconductor manufacturing line PC group 101.

An etched wafer is transferred to the semiconductor inspection device, the semiconductor analysis device, or the semiconductor analyzer in the base A. Then, a measurement recipe is input to the semiconductor manufacturing line PC group 101, and predetermined measurement is performed. A measurement result is stored in the semiconductor manufacturing line PC group 101.

The data route setting PC 103 determines accessibility and defines a data flow. The semiconductor manufacturing line PC group 101 assigns a device ID (identification information) to each semiconductor manufacturing device, stores and manages the device ID as a device master together with file extension of stored output data, transmits the device master to the server 104, and stores the device master in the server 104. Specifically, the semiconductor manufacturing line PC group 101 assigns a device ID for each semiconductor manufacturing device, manages the file extension of the output data output from the semiconductor manufacturing device in association with each device ID, and stores the device master in the server 104. Examples of the file extension include “.txt” indicating text data, “.gif” indicating image data, and “.csv” indicating a csv file.

When accessing the semiconductor manufacturing line PC group 101, only data matching the device master is collected with reference to the device ID and the device master of the file extension. Such a program is deployed in the gateway PC 102. A data collection program incorporated in the gateway PC 102 accesses the semiconductor manufacturing line PC group 101 according to a flow of the specified data and performs data collection. The collected data is stored in the server 104 in the base.

The server 104 may manage data by dividing the data into data that is permitted to be made public and data that is prohibited from being made public to an external network. In this case, the data may be managed in a database by dividing the data into categories or levels. For example, the data that is permitted to made public permits communication with other bases, and the data that is prohibited from being made public prohibits communication with other bases. Such a definition is defined by the data route setting PC 103.

The base B and the base C are bases that do not include the gateway PC 102 and the data route setting PC 103. In such a base, the data collection program of the gateway PC 102 can be used instead. For example, in the case of the base B, a system may be constructed in which data is collected and stored by operating the in-base PC 110, or a system may be constructed in which data is collected from the semiconductor manufacturing line PC group 111 and is saved in the server 114 without a user operation. In the case of the base C, a system may be constructed in which data is collected from other bases by operating the in-base PC 120 and the data is stored. Instead of the data route setting PC 103, access permission and a data flow can be regulated by providing setting for public permission or public prohibition based on a storage location. This makes it possible to operate a system similar to the gateway PC 102 and the data route setting PC 103 without using the gateway PC 102 and the data route setting PC 103.

Authentication information is registered to log in to the integrated platform 108 in the base A. This registration can be performed by the in-base PC 100 or the external PC 121. As the authentication information, a user ID and a password are registered, and authentication is performed at the time of login. A user logs in to the integrated platform 108 from the in-base PC 100 or the external PC 121 based on the authentication information. Thereafter, the user registers a device master in the integrated platform 108. Data can be transmitted to and received from other bases by using the integrated platform 108.

For example, when data is transmitted from the server 104 in the base A to the integrated platform 118 in the base B, the user ID and the password registered in the integrated platform 108 in the base A need to be registered in the integrated platform 118. This makes it possible to prevent unauthorized access from an external network to data in the integrated platform. Authentication of the integrated platform in other bases may be set for data transfer only so that browsing and editing of a database cannot be performed. This makes it possible to prevent leakage of confidential information to other bases. On the other hand, information of other bases can be shared by providing a function of permitting reception of data transmitted from other bases.

For example, a case where data is transferred from the base B to the base A will be described. Here, a user ID and a password are registered in the integrated platform 108 in the base A and the integrated platform 118 in the base B. First, a user selects data stored in a database of the server 114 in the base B as data to be transferred to the base A. The selection here can be performed by the in-base PC 110 or the external PC 121. In other words, the in-base PC 110 or the external PC 121 in the base B passes the authentication of the integrated platform 118 via the Internet 117, and accesses the server 114 in the base B. The selected data of the base B first passes the authentication of the integrated platform 108 in the base A and is transferred to and stored in the server 104.

Although etching processing cannot be performed in the base C where no semiconductor manufacturing device is provided, a recipe can be transferred to other bases. This makes it possible to perform etching processing in a form in which an evaluation request is made to other bases where a semiconductor manufacturing device is provided. Further, when transferring a recipe of a semiconductor manufacturing device, the transfer is performed by performing processing of converting the recipe into a recipe that can be processed by a semiconductor manufacturing device of a transfer destination.

The computer system 1 shown in FIG. 1 may be applied to the semiconductor manufacturing line PC groups 101 and 111, the in-base PCs 100 and 110, the gateway PC 102, the data route setting PC 103, and the servers 104, 114, and 124 in FIG. 2. Alternatively, these units may each include a graphical user interface (GUI) for a user to input a parameter value. The semiconductor manufacturing line PC groups 101 and 111 may be semiconductor manufacturing devices (a configuration including a computer in the semiconductor manufacturing device).

### <Processing Flow>

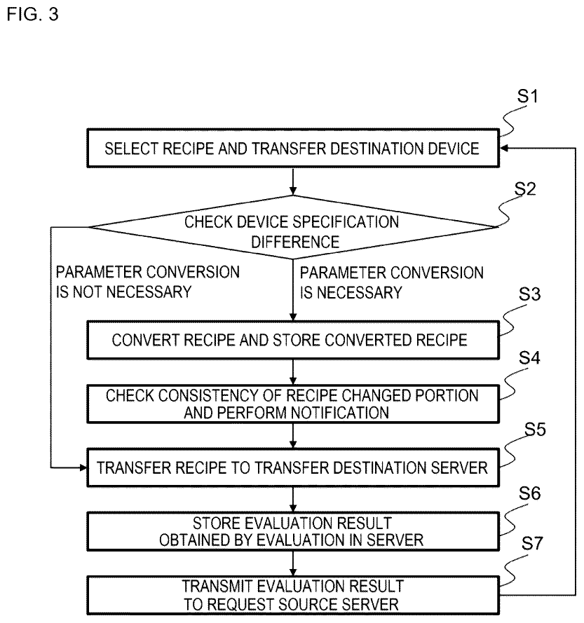

FIG. 3 is a diagram showing an example of a processing flow from selecting a recipe to be evaluated to transferring an evaluation result according to the invention. In FIG. 3, a flow from an evaluation request to transferring an evaluation result is described as an example of a case in which a recipe of a semiconductor manufacturing device such as an etching device is transferred from the base C to the base B.

In step S1, a recipe and a transfer destination device are selected. A user selects a recipe of a semiconductor manufacturing device to be evaluated and a semiconductor manufacturing device that is a transfer destination of the recipe from a database in the server 124 of the base C. Here, information on the recipe of the semiconductor manufacturing device to which a current evaluation target is to be transferred may be not present in the server 124 of the base C. The user selects a recipe for the semiconductor manufacturing device in the server 124 of the base C which is most suitable for manufacturing to be evaluated. This selection is performed by the in-base PC 120 in the base C or the external PC 121 used by a home worker or the like. In the case of the in-base PC 120, authentication of the integrated platform 128 is performed in the base C, and in the case of the external PC 121, authentication of the integrated platform 128 is performed through the Internet 127. When the recipe is transferred from the server 124, the user registers the recipe in the server 124 of the base C which is an own base by associating the recipe with a device ID of a semiconductor manufacturing device to be used.

Next, in step S2, a device specification difference is checked. This processing is performed by the server 124. Specifically, a device specification of the semiconductor manufacturing device associated with the recipe selected in step S1 is compared with a device specification of the semiconductor manufacturing device of a transfer destination. The device specifications are stored in the server 124 of the base C. A device is specified based on a device ID assigned to each device, which is stored in the server 124 of the base C. From the checked device specification difference, it is determined whether conversion of each parameter used for a device specification is necessary. When it is determined that the parameter conversion is necessary, the processing proceeds to step S3. On the other hand, when it is determined that the parameter conversion is not necessary, S3 and S4 are skipped and the processing proceeds to step S5.

Each parameter necessary for the recipe is defined in a device specification. The device specification difference in step S2 includes, for example, a type of power supply, the presence or absence of a function based on hardware, the presence or absence of a function based on software specification, a difference in parameter control ranges, and the presence or absence of a connected gas.

In step S3, the recipe is converted and the converted recipe is stored. This processing is performed by the server 124. When it is determined that the parameter conversion is necessary based on the device specification difference, a parameter based on a parameter conversion item is converted to be adapted to a parameter item of the semiconductor manufacturing device of the transfer destination. Accordingly, a recipe that can be processed by the semiconductor manufacturing device of the transfer destination is created. The created recipe is stored in the server 124 of the base C in association with the device ID of the semiconductor manufacturing device of the transfer destination. An existing recipe stored in the server 124 is not overwritten, but is stored as a new recipe.

Next, in step S4, a converted portion of the recipe and consistency are checked and notification is performed. This processing is performed by the server 124. In order to check whether the recipe after the parameter conversion can be processed by the semiconductor manufacturing device of the transfer destination, the consistency of the recipe is checked. Specifically, a recipe consistency check item of the device specification of the semiconductor manufacturing device of the transfer destination is read to check whether the recipe can be processed. When it is determined the recipe can be processed in the recipe consistency check, a parameter conversion item is stored in the server 124 of the base C. At this time, the in-base PC 120, the external PC 121, and the remote monitor 106 are notified of completion of normal recipe conversion. When it is determined the recipe cannot be processed in the consistency check, a parameter item that is problematic in the consistency check, an item subjected to the parameter conversion, and a device specification difference are recorded and notified to the server 124 of the base C. In this case, the notification is sent to the in-base PC 120 or the external PC 121. In this case, a user can correct the recipe to create a recipe that can be processed by the semiconductor manufacturing device of the transfer destination by performing an input operation based on the notified and recorded information via the in-base PC 120 or the external PC 121.

Next, in step S5, the recipe is transferred to a server of the transfer destination. In this processing, transfer processing is performed by the server 124, and storing is performed by the server 114. Specifically, the recipe to be transferred is transferred to the base B via the integrated platform 128 of the base C and the integrated platform 118 of the base B. At this time, the processing is performed via the Internet 127 and the Internet 117. The transferred recipe is stored in a database held by the server 114 of the base B.

Next, in step S6, an evaluation result obtained by evaluation is stored in a server. The recipe to be evaluated that is transferred to the server 114 of the base B is read from the server 114 of the base B to the semiconductor manufacturing line PC group 111 of the base B. Then, processing is actually performed by a semiconductor manufacturing device in the base B. An evaluation target subjected to the processing is evaluated using at least one of the semiconductor inspection device, the semiconductor analysis device, and the semiconductor analyzer in the base B. The evaluation here can be calculated by the semiconductor manufacturing line PC group 111. The evaluation includes checking whether an object to be evaluated is close to a target shape, a cutting amount, a machining degree, and the like. Transfer from the semiconductor manufacturing device to the semiconductor inspection device, the semiconductor analysis device, or the semiconductor analyzer may be automatically performed under the control of the semiconductor manufacturing line PC group 111. In this manner, data obtained by the evaluation is collected in a database in the server 114 of the base B. The data collection can be performed by a system in which the gateway PC described in FIG. 2 is used instead. Alternatively, the data may be registered in the server 114 by a user operating the in-base PCs 110 and 120 or the external PC 121.

Next, in step S7, the evaluation result is transmitted to a request source server. Specifically, the evaluation result obtained in step S6 is transferred from the server 114 of the base B to the server 124 of the base C via the Internets 117 and 127. At this time, data of the evaluation result passes through the integrated platform 118 of the base B and the integrated platform of the base C. Therefore, the evaluation result can be shared with other bases.

It is also possible to make an evaluation request by additional processing based on the evaluation result of the base B. It is possible to continue evaluation using a base other than the base B by registering a recipe to be requested for evaluation in a database in the server 124 of the base C and transferring the recipe.

### <Specific Example of Recipe Conversion Processing>

In steps S3 and S4 of FIG. 3, the recipe is converted and it is determined whether the converted recipe can be processed. A specific example thereof will be described.

For example, when an output before conversion cannot be used due to a difference in power supplies of the semiconductor manufacturing devices, an upper limit value of a power supply in the device specification of the transfer destination is changed. When the upper limit value can be changed to conform to the power supply of the device specification of the transfer destination, it is determined that the converted recipe can be processed in the consistency check, and it is notified that the conversion of the recipe is normally completed. Therefore, the power supply can be used in the semiconductor manufacturing device of the transfer destination. When the upper limit value cannot be changed to conform to the power supply, it is determined that the converted recipe cannot be processed in the consistency check, and a result is notified and recorded. In this case, the upper limit value of the power supply is a parameter item.

For example, in the device specification of the transfer destination, when a parameter that is not originally present is generated due to an increase in an item of stage temperature control, a new parameter item is set. In this case, a temperature of the new parameter can be calculated based on a conversion table prepared in advance, and the new parameter item can be calculated by the server 124. At this time, it is assumed that cooling water temperature setting of a stage is affected. In this case, a recipe value is changed so that both a stage temperature and a cooling water temperature are within a control range. When the new parameter item can be changed to conform to the stage temperature control of the device specification of the transfer destination, it is determined that the converted recipe can be processed in the consistency check, and it is notified that the conversion of the recipe is normally completed. When the new parameter item cannot be changed to conform to the stage temperature control, it is determined that the converted recipe cannot be processed in the consistency check, and a result is notified and recorded.

For example, when an etching gas to be used is not attached to a transfer destination device, it is necessary to change the etching gas to an alternative etching gas. In this case, it is notified that it is necessary to correct a recipe by a user input.

### <Recipe Creation Processing>

FIG. 4 is a diagram showing an example of a processing flow of creating a recipe according to the invention. In step S3 of FIG. 3, a parameter is converted to create a recipe. Here, an example of the parameter conversion will be described.

When a recipe is created, if there is a device specification difference, it is necessary to convert a parameter, add a parameter, and delete an unnecessary parameter so as to conform to a parameter item of the device specification of the transfer destination. A simplified specific example thereof will be described with reference to FIG. 4.

A recipe 301 of a device specification A is stored in a server 331, and parameters 1 to 4 shown in the recipe 301 are set. When the recipe of the device specification A is to be transferred to a device of a device specification B, a device specification difference is checked before the recipe is transferred. The device specification difference is determined by comparing device specifications based on a device ID that is assigned to each device and is stored in the server 331. When there is a device specification difference, a parameter that needs to be converted is determined based on a parameter conversion table. When it is determined that the parameter conversion is necessary, recipe conversion is performed based on the parameter conversion table so that a recipe 303 can be processed by the device of the device specification B. In the recipe conversion, an unnecessary parameter is deleted, a new parameter is added, and an existing parameter is converted.

After the recipe conversion, conversion contents and the converted recipe are stored in a database of the server 331. Specifically, the device specification difference between the device specification A and the device specification B, and the parameter conversion, added and deleted items serving as the recipe conversion are recorded as information in the server. Then, a user is notified of an item subjected to the recipe conversion, and the user can confirm parameter change contents.

For example, in the device specification A, it is assumed that control is performed by parameters 3 and 4 related to temperature control. On the other hand, in the case of the device specification B, since the temperature control is performed only by the parameter 3, the parameter 4 is not necessary and is to be deleted. Although a parameter 5 does not exist in the device specification A, the parameter 5 exists in the device specification B. In this case, the parameter 5 is added. Regarding the added new parameter, as described above, it is possible to calculate a value of the parameter from other parameters based on the conversion parameter and input the calculated value, input an initial value, or the like. A numerical value of the parameter 2 is converted from “100” to “110”. The value can be changed by using a conversion formula or the like predetermined in a parameter conversion table or the like based on a device specification difference.

For example, when a temperature control range is increased from three to four, a fourth item can be set based on data of the remaining three items such that the same temperature control is performed. In a setting method, a calculation formula is prepared in advance, and the fourth parameter is generated by processing in the server 331. As a new necessary parameter such as the parameter 5 in FIG. 4, a parameter of an initial value can be input. In the device specification B, when the initial value is 5, a value of 5 is input. The initial value can be recorded in advance in a parameter conversion item in the server 331. The initial value can also be input by the server 331.

An error may occur due to a failure such as a parameter 1 in a recipe 302 after conversion into the device specification B. In the recipe 302, an error such as “parameter 1=4 (error)” is recorded. In such a case, it is necessary to change the recipe by a user input.

Examples of a cause of the error include the following. A first cause is a case where a conversion parameter item is not registered. A second cause is a case where information related to latest software is not registered or a case where a trouble due to data update occurs. A third cause is a trouble caused by a user due to a parameter-specific setting by the user. For example, a parameter set by a user is not within an allowable range. A fourth cause is a device problem, for example, an etching gas to be used is not connected.

When an error occurs, the error is notified when consistency of recipe conversion is notified. In the example shown in FIG. 3, corresponding to step S4, the in-base PC 120, the external PC 121, and the remote monitor 106 are notified of the error. A user can recognize a cause of the error by checking notified error contents and conversion item. Further, the user uses a recipe editor 313 in the example shown in FIG. 4 to remove the error (input “0” to the parameter 1) based on the cause of the error. The processing of removing the error is, for example, changing a problematic conversion parameter item, and updating software data. Accordingly, the user uses the recipe editor 313 to change a parameter so that a recipe based on the device specification B can be processed. The created recipe is stored in the server 331 in association with a device ID of the device specification B of the transfer destination, and a changed item remains as a history.

The server 331 in FIG. 4 corresponds to the server 124 in the example shown in FIG. 3, and the recipe editor 313 in FIG. 4 corresponds to the in-base PC 120 or the external PC 121 in the example shown in FIG. 3.

### <Effects>

According to the embodiment described above, it is possible to transfer a recipe of a semiconductor manufacturing device between different bases. It is possible to transfer and evaluate the recipe from a base where a semiconductor manufacturing device is not provided. At this time, even when a specification of a corresponding semiconductor manufacturing device is different, the recipe can be appropriately changed and applied. In particular, the recipe can be effectively applied to a case where a device specification is different by changing, deleting, or adding a parameter to match the device specification. Therefore, it is possible to shorten a time up to when evaluation is started after the recipe is transferred to a semiconductor manufacturing device at another base. Further, data can be transmitted to and received from an integrated platform of each base, and information can be easily shared between bases. Accordingly, it is possible to reduce manual work of converting and checking a recipe, prevent a device trouble caused by an operation error, and shorten work time. Since authentication of the integrated platform is required when a server in a base transmits data, security can be enhanced. In a case where an error occurs when a recipe is changed, a user is notified of the error so that the error can be corrected by a user operation, thereby improving versatility.

The invention is not limited to the embodiment described above, and includes various modifications. For example, the embodiment described above has been described in detail to facilitate understanding of the invention, and the invention is not necessarily limited to those including all the configurations described above. A part of a configuration of a certain embodiment can be replaced with a configuration of another embodiment, and the configuration of another embodiment can be added to the configuration of a certain embodiment. In addition, a part of a configuration in each embodiment may be added to, deleted from, or replaced with another configuration.

For example, although FIG. 2 shows an example of three bases A, B, and C, the number of bases may any number as long as the number is multiple, and may be three or more. Alternatively, it is sufficient to determine whether the gateway PC, the data route setting PC, and the semiconductor manufacturing line PC group are provided in each base.

The “PC” of the semiconductor manufacturing line PC groups 101 and 111, the in-base PCs 100 and 110, the gateway PC 102, and the data route setting PC 103 is a small computer such as a personal computer. Alternatively, the PC is not limited thereto and may be a general computer. For example, a virtual area, a server, or a mobile terminal may be used instead of a PC terminal. In addition, various communication methods can be used. For example, not only server message block (SMB) communication but also file transfer protocol (FTP) communication, network file system (NFS) communication, or the like may be used, and conversely, even the remote monitor 106 is a PC, the same effect can be obtained.

In FIG. 3, although a flow of transferring a recipe from the base C to the base B is described, the invention is not limited thereto. For example, the invention can be applied to a flow of transferring a recipe from the base C to the base A, from the base B to the base A, and from the base A to the base B in a similar manner. For example, when a recipe is transferred from the base A to the base B, a recipe of the semiconductor manufacturing device in the base A can be transferred in a manner of being adapted to a recipe of the semiconductor manufacturing device in the base B.

In FIGS. 2 to 4, although a device specification and a recipe of a semiconductor manufacturing device are described, the invention can be applied to an evaluation device in a similar manner, such as a semiconductor inspection device, a semiconductor analysis device, and a semiconductor analyzer.

The present specification includes disclosure of the following aspects.

### (Aspect 1)

A semiconductor device manufacturing system for transferring a manufacturing condition of a first semiconductor manufacturing device in a first base to a second semiconductor manufacturing device in a second base to process a sample by the second semiconductor manufacturing device, in which
when a specification of the first semiconductor manufacturing device and a specification of the second semiconductor manufacturing device are different from each other and the manufacturing condition of the first semiconductor manufacturing device is transferred to the second semiconductor manufacturing device, a manufacturing condition generated by adapting a parameter item in the manufacturing condition of the first semiconductor manufacturing device to a parameter item in a manufacturing condition of the second semiconductor manufacturing device is transferred to the second semiconductor manufacturing device.

### (Aspect 2)

The semiconductor device manufacturing system according to the aspect 1, in which
adapting a parameter item in the manufacturing condition of the first semiconductor manufacturing device to a parameter item in the manufacturing condition of the second semiconductor manufacturing device includes deleting, converting, or adding a parameter.

### (Aspect 3)

The semiconductor device manufacturing system according to the aspect 2, in which
deleting the parameter is processing of deleting a parameter that is not used by the second semiconductor manufacturing device.

### (Aspect 4)

The semiconductor device manufacturing system according to the aspect 2 or 3, in which
converting the parameter is processing of converting the parameter so as to satisfy a parameter range defined by the specification of the second semiconductor manufacturing device.

### (Aspect 5)

The semiconductor device manufacturing system according to any one of the aspect 2 to the aspect 4, in which
adding the parameter is processing of adding a new parameter when the new parameter is required in the second semiconductor manufacturing device.

### (Aspect 6)

The semiconductor device manufacturing system according to the aspect 5, in which
a value of the new parameter is a preset initial value or a value calculated from another parameter.

### (Aspect 7)

The semiconductor device manufacturing system according to any one of the aspect 1 to the aspect 6, including:
a GUI for a user to input, when there is an unadaptable parameter, a value of the parameter.
   (aspect 8)

The semiconductor device manufacturing system according to any one of the aspect 1 to the aspect 7, further including:
a platform on which an application is mounted, in which
the application transfers the manufacturing condition of the first semiconductor manufacturing device in the first base to the second semiconductor manufacturing device in the second base.
   (aspect 9)

A server for transferring a manufacturing condition of a first semiconductor manufacturing device in a first base to a second semiconductor manufacturing device in a second base to process a sample by the second semiconductor manufacturing device, in which
when a specification of the first semiconductor manufacturing device and a specification of the second semiconductor manufacturing device are different from each other and the manufacturing condition of the first semiconductor manufacturing device is transferred to the second semiconductor manufacturing device, a manufacturing condition generated by adapting a parameter item in the manufacturing condition of the first semiconductor manufacturing device to a parameter item in a manufacturing condition of the second semiconductor manufacturing device is transferred to the second semiconductor manufacturing device.

### (Aspect 10)

A semiconductor device manufacturing method for transferring a manufacturing condition of a first semiconductor manufacturing device in a first base to a second semiconductor manufacturing device in a second base to process a sample by the second semiconductor manufacturing device, the semiconductor device manufacturing method including:
when a specification of the first semiconductor manufacturing device and a specification of the second semiconductor manufacturing device are different from each other and the manufacturing condition of the first semiconductor manufacturing device is transferred to the second semiconductor manufacturing device, transferring to the second semiconductor manufacturing device a manufacturing condition generated by adapting a parameter item in the manufacturing condition of the first semiconductor manufacturing device to a parameter item in a manufacturing condition of the second semiconductor manufacturing device.

### REFERENCE SIGNS LIST

1: computer system
2: processor
2A, 2B: processing device
4: memory
6: memory bus
8: I/O bus
9: bus interface unit
10: I/O bus interface unit
12: terminal interface unit
14: storage interface
16: I/O device interface
18: network interface
20: user I/O device
22: storage device
24: display system
26: display device
30: network
50: latent factor specifying application
100: in-base PC
101: semiconductor manufacturing line PC group
102: gateway PC
103: data route setting PC
104: server
106: remote monitor
107: Internet
108: integrated platform
110: in-base PC
111: semiconductor manufacturing line PC group
114: server
117: Internet
118: integrated platform
120: in-base PC
121: external PC
124: server
127: Internet
128: integrated platform
301: recipe
302: recipe
303: recipe
313: recipe editor
331: server

1. A semiconductor device manufacturing system for transferring a manufacturing condition of a first semiconductor manufacturing device in a first base to a second semiconductor manufacturing device in a second base to process a sample by the second semiconductor manufacturing device, wherein
when a specification of the first semiconductor manufacturing device and a specification of the second semiconductor manufacturing device are different from each other and the manufacturing condition of the first semiconductor manufacturing device is transferred to the second semiconductor manufacturing device, a manufacturing condition generated by adapting a parameter item in the manufacturing condition of the first semiconductor manufacturing device to a parameter item in a manufacturing condition of the second semiconductor manufacturing device is transferred to the second semiconductor manufacturing device.

2. The semiconductor device manufacturing system according to claim 1, wherein
adapting a parameter item in the manufacturing condition of the first semiconductor manufacturing device to a parameter item in the manufacturing condition of the second semiconductor manufacturing device includes deleting, converting, or adding a parameter.

3. The semiconductor device manufacturing system according to claim 2, wherein
deleting the parameter is processing of deleting a parameter that is not used by the second semiconductor manufacturing device.

4. The semiconductor device manufacturing system according to claim 2, wherein
converting the parameter is processing of converting the parameter so as to satisfy a parameter range defined by the specification of the second semiconductor manufacturing device.

5. The semiconductor device manufacturing system according to claim 2, wherein
adding the parameter is processing of adding a new parameter when the new parameter is required in the second semiconductor manufacturing device.

6. The semiconductor device manufacturing system according to claim 5, wherein
a value of the new parameter is a preset initial value or a value calculated from another parameter.

7. The semiconductor device manufacturing system according to claim 1, comprising:
a GUI for a user to input, when there is an unadaptable parameter, a value of the parameter.

8. The semiconductor device manufacturing system according to claim 1, further comprising:
a platform on which an application is mounted, wherein
the application transfers the manufacturing condition of the first semiconductor manufacturing device in the first base to the second semiconductor manufacturing device in the second base.

9. A server for transferring a manufacturing condition of a first semiconductor manufacturing device in a first base to a second semiconductor manufacturing device in a second base to process a sample by the second semiconductor manufacturing device, wherein
when a specification of the first semiconductor manufacturing device and a specification of the second semiconductor manufacturing device are different from each other and the manufacturing condition of the first semiconductor manufacturing device is transferred to the second semiconductor manufacturing device, a manufacturing condition generated by adapting a parameter item in the manufacturing condition of the first semiconductor manufacturing device to a parameter item in a manufacturing condition of the second semiconductor manufacturing device is transferred to the second semiconductor manufacturing device.

10. A semiconductor device manufacturing method for transferring a manufacturing condition of a first semiconductor manufacturing device in a first base to a second semiconductor manufacturing device in a second base to process a sample by the second semiconductor manufacturing device, the semiconductor device manufacturing method comprising:
when a specification of the first semiconductor manufacturing device and a specification of the second semiconductor manufacturing device are different from each other and the manufacturing condition of the first semiconductor manufacturing device is transferred to the second semiconductor manufacturing device, transferring to the second semiconductor manufacturing device a manufacturing condition generated by adapting a parameter item in the manufacturing condition of the first semiconductor manufacturing device to a parameter item in a manufacturing condition of the second semiconductor manufacturing device.
